(19) United States
(12) Patent Application Publication
(10) Pub. No.: US 2015/0296614 A1
(43) Pub. Date: Oct. 15, 2015

(54) CROSSLINKED FLUOROPOLYMER CIRCUIT MATERIALS, CIRCUIT LAMINATES, AND METHODS OF MANUFACTURE THEREOF

(71) Applicant: Rogers Corporation, Rogers, CT (US)

(72) Inventors: Shawn Paul Williams, Andover, MA (US); Ronald Paul Boisvert, Chandler, AZ (US)

(21) Appl. No.: 14/681,134

(22) Filed: Apr. 8, 2015

Related U.S. Application Data
(60) Provisional application No. 61/977,872, filed on Apr. 10, 2014.

(51) Int. Cl. H05K 1/05; H05K 3/02

(52) U.S. Cl. CPC H05K 1/056; H05K 3/022; H05K 2203/065; H05K 2203/06

(57) ABSTRACT

Circuit subassemblies comprising a conductive layer disposed on a dielectric substrate layer, wherein the dielectric substrate layer comprises a crosslinked fluoropolymer.

### CROSS-REFERENCE TO RELATED APPLICATIONS

This application claims the benefit of priority to U.S. provisional application No. 61/977,872 filed on Apr. 10, 2014, the entire contents of which are incorporated herein by reference.

### BACKGROUND

This disclosure generally relates to crosslinked fluoropolymer circuit materials, methods for the manufacture of the circuit materials, and articles formed therefrom, including circuits and circuit laminates.

As used herein, a circuit material is an article used in the manufacture of circuits and multi-layer circuits, and includes circuit subassemblies, bond plies, resin-coated conductive layers, unclad dielectric layers, free films, and cover films. A circuit laminate is a type of circuit subassembly that has a conductive layer, e.g., copper, fixedly attached to a dielectric layer. Double clad circuit laminates have two conductive layers, one on each side of the dielectric layer. Patterning a conductive layer of a laminate, for example by etching, provides a circuit. Multilayer circuits comprise a plurality of conductive layers, at least one of which contains a conductive wiring pattern. Typically, multilayer circuits are formed by laminating one or more circuits together using bond plies, by building up additional layers with resin coated conductive layers that are subsequently etched, or by building up additional layers by adding unclad dielectric layers followed by additive metallization. After forming the multilayer circuit, known hole-forming and plating technologies can be used to produce useful electrical pathways between conductive layers.

Circuit materials include a dielectric material that can be an organic polymer. The polymers can be combined with fillers such as silica to adjust the dielectric or other properties of the polymers. For example, circuit subassembly dielectrics have been made with glass fabric-reinforced epoxy resins. The relatively polar epoxy material bonds comparatively well to metallic surfaces such as copper foil. However, the polar groups in the epoxy resin also lead to a relatively high dielectric constant and high dissipation factor. Better electrical performance in some instances is achieved by using comparatively nonpolar polymer systems, such as those based on polybutadiene, polyisoprene, or polyphenylene oxide. An unwanted consequence of the lower polarity of these resin systems, however, is an inherently lower bond to metallic surfaces.

In addition, as electronic devices and the features thereon become smaller, manufacture of dense circuit layouts is facilitated by use of circuit dielectric materials with a high glass transition temperature. However, when dielectric substrates with low dielectric constants, low dissipation factors, and high glass transition temperatures are used, adhesion between the conductive layer and the dielectric substrate layer can be reduced. Adhesion can be even more severely reduced when the conductive layer is a low or very low roughness copper foil (low profile copper foil). Such foils can be used in dense circuit designs to improve the etch definition and in high frequency applications to lower the conductor loss due to roughness. A number of efforts have been made to improve the bonding between dielectric circuit substrates and the conductive layer surface.

In view of the above, there remains a need in the art for dielectric materials that possess desirable processing and fabrication characteristics, and yet provide overall improved dielectric performance, particularly at high frequencies. It would be a further advantage if the dielectric materials could be used in thin devices.

### SUMMARY

The above-described drawbacks and disadvantages are alleviated by a circuit material comprising a crosslinked fluoropolymer dielectric material. In particular, a circuit subassembly comprises a conductive layer disposed on a dielectric layer, wherein the dielectric layer comprises a crosslinked fluoropolymer.

Circuits comprising the circuit subassemblies are also described.

In another aspect, a method of making a circuit subassembly comprises disposing a conductive layer on a dielectric layer comprising the crosslinked fluoropolymer dielectric material; and laminating the dielectric layer and the conductive layer.

The invention is further illustrated by the following drawings, detailed description, and examples.

### BRIEF DESCRIPTION OF DRAWINGS

Referring now to the exemplary drawings wherein like elements are numbered alike in the figures:

FIG. 1 is a schematic of a single clad laminate;

FIG. 2 is a schematic of a double clad laminate;

FIG. 3 is a schematic of a double clad laminate with a patterned conductive layer; and

FIG. 4 is a schematic of an exemplary circuit assembly comprising two double clad circuit laminates.

### DETAILED DESCRIPTION

Thermoplastic fluoropolymers are one of the lowest loss polymer systems available for printed circuit boards. Fluoropolymers, however, are not readily amenable to low cost manufacturing processes. In addition, fluoropolymers can have other performance limitations such as high CTE, high processing temperature requirements, and extreme chemical resistance. These characteristics can limit the broad use of fluoropolymers in printed circuit boards.

Provided herein are circuit materials in which the dielectric material (e.g., a dielectric substrate layer) includes a crosslinked fluoropolymer. The crosslinked fluoropolymers can exhibit reduced or lower coefficients of thermal expansion (CTE) relative to fluoropolymers without crosslinked functionality, as well as improved overall dielectric performance. The crosslinking capability allows processing of the fluoropolymers using thermoset fabrication processing methods. The uncrosslinked polymers can have improved melt rheology and lower temperature processing temperatures. The fluoropolymers can also be manufactured to meet current flame retardancy standards. In some aspects, the dielectric layer comprises one or more fillers. Addition of fillers to the fluoropolymers can provide improved rigidity and creep resistance.

The fluoropolymers can be fluorinated homopolymers or copolymers. In some embodiments, the fluoropolymer is a polymer of tetrafluoroethylene, vinylidene fluoride, vinyl fluoride, perfluoroether, tetrafluoroethylene-perfluoropropylene vinyl ether, chlorotrifluoroethylene, or a combination comprising at least one of the foregoing. When a comonomer is present, the comonomer can be, for example, perfluoromethyl vinyl ether, perfluoropropylene vinyl ether, hexafluoropropylene, perfluorobutyl ethylene, ethylene, propylene, butylene, or a combination comprising at least one of the foregoing. Specific fluoropolymers are polytetrafluoroethylene (PTFE), polychlorotrifluoroethylene (PCTFE), polyvinylidene fluoride, polyvinyl fluoride, tetrafluoroethylene-perfluoroproplyene vinyl ether copolymer (also known as PFA), tetrafluoroethylene-hexafluoropropylene copolymer, and tetrafluoroethylene-ethylene copolymer. A combination comprising at least one of the foregoing homopolymers and copolymers can be used.

The fluoropolymers are rendered crosslinkable by the inclusion of crosslinkable monomers into the backbone of the fluoropolymers, which includes the terminal ends of the fluoropolymers. The amount and type of crosslinking functionality is selected so as not to substantially degrade electrical performance, CTE, and other important performance features of the dielectric materials, while also incorporating positive attributes of cross-linking functionality. Depending on the type of backbone the inclusion of a small percent (e.g., 0.1 to 15% by weight) of crosslinking monomer can interfere with the tendency of the fluoropolymer to crystallize, and consequently, can increase the creep resistance of the resulting dielectric composition and positively impact the rheology of the polymer during processing. It is thus believed that the inclusion of a cross-linkable moiety in the fluoropolymer allows the cross-linking capability to provide significant processing and performance advantages.

The crosslinkable monomer can be crosslinked by any thermally, chemically, or photoinitiated cross-linking technologies known to those skilled in the art, depending upon the resulting properties desired. An exemplary crosslinking functionality includes (meth)acrylates, which includes both acrylates and methacrylates. For example U.S. Pat. Nos. 8,580,897 and 8,394,870 describe a crosslinkable fluoropolymer of the formula

H₂C═CR′COO—(CH₂)ₙ—R—(CH₂)ₙ—OOCR′═CH₂

wherein R is an oligomer of a fluorinated monomer or comonomer as described above, R′ is H or —CH₃, and n is 1-4. In some embodiments, R is i) an oligomer comprising copolymerized units of vinylidene fluoride and perfluoro(methyl vinyl ether), ii) an oligomer comprising copolymerized units of vinylidene fluoride and hexafluoropropylene, iii) oligomer comprising copolymerized units of tetrafluoroethylene and perfluoro(methyl vinyl ether), or iv) an oligomer comprising copolymerized units of tetrafluoroethylene and a hydrocarbon olefin. In some embodiments, the oligomer comprises copolymerized units selected from the group consisting of i) vinylidene fluoride, tetrafluoroethylene and perfluoro(methyl vinyl ether); ii) tetrafluoroethylene, perfluoro(methyl vinyl ether) and ethylene; iii) vinylidene fluoride, hexafluoropropylene and tetrafluoroethylene; and iv) tetrafluoroethylene, vinylidene fluoride and propylene. The oligomer can have a number average molecular weight of 1000 to 25,000 Daltons. The crosslinked fluoropolymer networks can be made by exposing the diacrylate fluoropolymer to a source of free radicals in order to initiate a radical crosslinking reaction through the terminal acrylate groups on the fluoropolymer. The source of the free radicals may be a UV light sensitive radical initiator (i.e. a photoinitiator or UV initiator) or the thermal decomposition of an organic peroxide. Suitable photoinitiators and organic peroxides are well known in the art. Crosslinkable fluoropolymers are commercially available, for example a terpolymer of vinylidene fluoride, hexafluoropropylene, and tetrafluoroethylene comprising 50-82% of vinylidene fluoride monomer units having <1% of monomer units providing an iodine cure site, available under the name Viton® B from the DuPont Company. In crosslinking Viton® B , a 10 parts per hundred of triallyisocyanurate (TAIC) and 10 parts per hundred of a photoinitiator such as IRGACURE® 907 from Ciba-Geigy can be used.

The crosslinked fluoropolymer can be used and incorporated in various forms and combinations of dielectric materials. For example, the fluoropolymers can be used as the only polymer in the dielectric material, or together with other dielectric polymers. In particular, the fluoropolymers can be used with other polymers as a mixture of polymers or as separate layers with other polymers. For example, thermosetting polybutadiene and/or polyisoprenes can be used in conjunction with the crosslinked fluoropolymers. Exemplary other dielectric polymers include low polarity, low dielectric constant and low loss polymers such as 1,2-polybutadiene (PBD), polyisoprene, polybutadiene-polyisoprene copolymers, polyetherimide (PEI), polyimide, polyetheretherketone (PEEK), polyamidimide, polyethylene terephthalate (PET), polyethylene naphthalate, polycyclohexylene terephthalate, epoxies, polyphenylene ethers, allylated polyphenylene ethers, copolymers of ethylene and propylene monomers (EPM), and terpolymers of ethylene, propylene, and diene monomers (EPDM), unsaturated polybutadiene- or polyisoprene-containing elastomers, homopolymers or copolymers of ethylene such as polyethylene and ethylene oxide copolymers; natural rubber; norbornene polymers such as polydicyclopentadiene; hydrogenated styrene-isoprene-styrene copolymers and butadiene-acrylonitrile copolymers; unsaturated polyesters; and the like.

The relative amount of the various polymers, for example the crosslinked fluoropolymers and optionally, other polymers, can vary depend on the particular conductive metal layer used, the desired properties of the circuit materials and circuit laminates, and like considerations. Determination of the appropriate quantities of each component can be done without undue experimentation, depending on the desired properties. For example, levels of these copolymers are generally less than 50 wt. % of the total dielectric polymer, for example 0.1 to 30 wt. %., or 1 to 10 wt. %.

Free radical-curable monomers can also be added for specific property or processing modifications, for example to increase the crosslink density of the fluoropolymer network after cure. Exemplary monomers that can be suitable crosslinking agents include, for example, di, tri-, or higher ethylenically unsaturated monomers such as divinyl benzene, triallyl cyanurate, diallyl phthalate, and multifunctional acrylate monomers (e.g., Sartomer® resins available from Sartomer USA, Newtown Square, Pa.), or combinations thereof, all of which are commercially available. The crosslinking agent, when used, can be present in dielectric polymer system in an amount of up to about 20 wt. %, specifically 1 to 15 wt. %, based on the total composition.

A curing agent can be used to accelerate the curing reaction. For crosslinking groups having olefinic reactive sites, useful curing agents are organic peroxides such as dicumyl peroxide, t-butyl perbenzoate, 2,5-dimethyl-2,5-di(t-butyl peroxy)hexane, α,α-di-bis(t-butyl peroxy)diisopropylbenzene, and 2,5-dimethyl-2,5-di(t-butyl peroxy) hexyne-3, all of which are commercially available. They can be used alone or in combination. Typical amounts of curing agent are from about 1.5 to about 10 wt. % of the total polymer composition.

In addition to the fluoropolymer, the dielectric composite material can optionally further include woven, thermally stable webs of a suitable fiber, specifically glass (E, S, and D glass) or high temperature polyester fibers. Such thermally stable fiber reinforcement can provide a circuit laminate with a means of controlling shrinkage upon cure within the plane of the laminate. In addition, the use of the woven or nonwoven web reinforcement renders a circuit substrate with a relatively high mechanical strength.

In certain aspects, the dielectric material comprises the fluoropolymer system and a filler component to provide a dielectric composite material for use in circuit materials (e.g., circuit subassemblies and bond plies). Use of fillers can allow the dielectric constant, dissipation factor, coefficient of thermal expansion, and other properties of the dielectric composite material to be fine-tuned.

Examples of particulate fillers include, without limitation, titanium dioxide (rutile and anatase), barium titanate, strontium titanate, silica (including fused amorphous silica), corundum, wollastonite, Ba₂Ti₉O₂₀, solid glass spheres, synthetic glass or ceramic hollow spheres, quartz, boron nitride, aluminum nitride, silicon carbide, beryllia, alumina, alumina trihydrate, magnesia, mica, talcs, nanoclays, and magnesium hydroxide. A single filler, or a combination of fillers, can be used to provide a desired balance of properties. Optionally, the fillers can be surface treated with a silicon-containing coating, for example, an organofunctional alkoxy silane coupling agent. Alternatively, a zirconate or titanate coupling agent can be used. Such coupling agents can improve the dispersion of the filler in the polymeric matrix and reduce water absorption of the finished composite circuit substrate. In addition or alternatively, the filler(s) can include microspheres, in particular certain borosilicate microspheres as a particulate filler in the dielectric composite materials to allow the manufacture of circuit subassemblies having an improved dissipation factor and reduced dielectric constant. The density of the hollow microspheres can range from 0.1 to 0.5, specifically less than 0.40, more specifically 0.16 g/cc to 0.380 g/cc.

The crosslinked fluoropolymers described herein can also be used in bond plies and cover films and other circuit materials, for example circuit laminates. Increasing the glass transition temperature (Tg) and/or creep resistance and decreasing the coefficient of thermal expansion (CTE) of a fluoropolymer in a circuit board dielectric material by crosslinking as described herein can increase the high temperature performance of the resulting material. The materials can further have dielectric constant Dₖ of less than 3.5, a dissipation factor D_{f} of less than 0.004. In some embodiments, the circuit subassembly exhibits a dissipation factor of 0.0030 to 0.0035 at 10 GHz, a PIM of less than −153 dBc, and a dielectric constant that can be adjusted to 1 to 13, for example from 2 to 7, from 2.5 to 3, or from 2 to 9, depending on the fluoropolymer, the degree of crosslinking, and the type and amount of filler or fillers.

Methods of making circuit materials, including circuit subassemblies and bond plies, include forming a dielectric layer comprising a crosslinked fluoropolymer. The fluoropolymer can be partially cured, or B-staged to form a bond ply.

To prepare a circuit subassembly such as a circuit laminate or a resin-coated conductive layer, the method comprises disposing a conductive layer on the dielectric substrate layer; and laminating the dielectric substrate layer and the conductive layer. Alternatively, the layers can be partially cured, or B-staged, and then laminated. Such methods can also include disposing a second conductive layer (e.g., copper foil) on a side of the dielectric substrate layer opposite the first conductive layer (e.g., copper foil). Such methods can additionally include etching one or more of the conductive layer(s) to provide a circuit(s).

The dielectric material layer can be produced by means known in the art. The particular choice of processing conditions can depend on the polymer matrix selected. For example, where the polymer matrix is a fluoropolymer such as PTFE, the polymer matrix material can be mixed with a first carrier liquid. The mixture can comprise a dispersion of polymeric particles in the first carrier liquid, i.e. an emulsion, of liquid droplets of the polymer or of a monomeric or oligomeric precursor of the polymer in the first carrier liquid, or a solution of the polymer in the first carrier liquid. If the polymer component is liquid, then no first carrier liquid may be needed.

The choice of the first carrier liquid, if present, is based on the particular polymeric matrix material and the form in which the polymeric matrix material is to be introduced to the dielectric composite material. If it is desired to introduce the polymeric material as a solution, a solvent for the particular polymeric matrix material is chosen as the carrier liquid, e.g. N-methyl pyrrolidone (NMP) would be a suitable carrier liquid for a solution of a polyimide. If it is desired to introduce the polymeric matrix material as a dispersion, then a suitable carrier liquid is a liquid in which the matrix material is not soluble, e.g. water would be a suitable carrier liquid for a dispersion of PTFE particles and would be a suitable carrier liquid for an emulsion of polyamic acid or an emulsion of butadiene monomer.

The filler component can optionally be dispersed in a suitable second carrier liquid, or mixed with the first carrier liquid (or liquid polymer where no first carrier is used). The second carrier liquid can be the same liquid or can be a liquid other than the first carrier liquid that is miscible with the first carrier liquid. For example, if the first carrier liquid is water, the second carrier liquid can comprise water or an alcohol. In an exemplary embodiment, the second carrier liquid is water.

The filler dispersion can include a surfactant in an amount effective to modify the surface tension of the second carrier liquid to enable the second carrier liquid to wet the filler. Exemplary surfactant compounds include ionic surfactants and nonionic surfactants. Triton X-100®, commercially available from Dow Chemical, has been found to be an exemplary surfactant for use in aqueous filler dispersions. Generally, the filler dispersion comprises from about 10 vol. % to about 70 vol. % of filler and from about 0.1 vol. % to about 10 vol. % of surfactant, with the remainder comprising the second carrier liquid.

The mixture of the polymeric matrix material and first carrier liquid and the filler dispersion in the second carrier liquid can be combined to form a casting mixture. The relative amounts of the polymeric matrix material and the filler component in the casting mixture are selected to provide the desired amounts in the final composition.

The viscosity of the casting mixture can be adjusted by the addition of a viscosity modifier, selected on the basis of its compatibility in a particular carrier liquid or mixture of carrier liquids, to retard separation, i.e., sedimentation or flotation, of the filler from the dielectric composite material, and to provide a dielectric composite material having a viscosity compatible with conventional laminating equipment. Exemplary viscosity modifiers suitable for use in aqueous casting mixtures include, e.g. polyacrylic acid compounds, vegetable gums, and cellulose based compounds. Specific examples of viscosity modifiers include polyacrylic acid, methyl cellulose, polyethyleneoxide, guar gum, locust bean gum, sodium carboxymethylcellulose, sodium alginate, and gum tragacanth. The viscosity of the viscosity-adjusted casting mixture can be further increased, i.e., beyond the minimum viscosity, on an application by application basis to adapt the dielectric composite material to the selected laminating technique. In an exemplary embodiment, the viscosity-adjusted casting mixture exhibits a viscosity between about 10 centipoise (cp) and about 100,000 cp; specifically about 100 cp and 10,000 cp. It will be appreciated by those skilled in the art that the foregoing viscosity values are room temperature values.

Alternatively, the viscosity modifier can be omitted if the viscosity of the carrier liquid is sufficient to provide a casting mixture that does not separate during the time period of interest. Specifically and for example, in the case of extremely small particles, e.g. particles having an equivalent spherical diameter less than 0.1 micrometers, the use of a viscosity modifier may not be necessary.

A layer of the viscosity-adjusted casting mixture can be cast on a substrate by conventional methods, e.g. dip coating, reverse roll coating, knife-over-roll, knife-over-plate, and metering rod coating. Examples of carrier materials can include metallic films, polymeric films, ceramic films, and the like. Specific examples of carriers include stainless steel foil, polyimide films, polyester films, and fluoropolymer films. Alternatively, the casting mixture can be cast onto a glass web, or a glass web can be dip-coated.

The carrier liquid and processing aids, i.e., the surfactant and viscosity modifier, are removed from the cast layer, for example by evaporation and/or by thermal decomposition, to consolidate a dielectric layer of the polymeric matrix material and any filler, including filler comprising hollow microspheres.

The layer of the polymeric matrix material and filler component can be further heated to modify the physical properties of the layer, e.g. to sinter a thermoplastic matrix material or to cure and/or post cure a thermosetting matrix material.

In another method, a PTFE composite dielectric material can be made by the paste extrusion and calendaring process taught in U.S. Pat. No. 5,358,775.

In another embodiment, if the Tg of the uncrosslinked fluoropolymer is sufficiently low, the polymer can be softened or melted, combined with any filler or other additives, and cast or extruded to form the dielectric layer.

Useful conductive layers for the formation of the circuit materials circuit laminates can include, without limitation, stainless steel, copper, gold, silver, aluminum, zinc, tin, lead, transition metals, and alloys comprising at least one of the foregoing, with copper being exemplary. Suitable conductive layers include a thin layer of a conductive metal such as a copper foil presently used in the formation of circuits, for example, electrodeposited copper foils.

In some embodiments, the lamination process entails placing one or more layers of the dielectric composite material between one or more coated or uncoated conductive layers to form a stack. The conductive layer can be in direct contact with the dielectric composite material, specifically without an intervening layer. Alternatively, an adhesive or bond ply layer can be located between the conductive layer and the dielectric layer. The relative thickness of the bond ply layer to the dielectric layer can vary depending on the materials employed and desired application or intended use. For example and while not to be construed as limiting, the bond ply layer can be less than 70%, less than 50%, less than 30%, or less than 10% of the thickness of the dielectric layer, and as low as 1% of the thickness of the dielectric layer. In other aspects, the bond ply layer and the dielectric material for example can have similar or the same thicknesses.

The multi-layer stack is then laminated under heat and pressure. Suitable conditions for the lamination can be readily determined by one of ordinary skill in the art without undue experimentation using the guidance provided herein, and will depend on factors such as the softening or melt temperature of the polymer and the thickness of the substrate. Exemplary conditions are 250 to 450° C., preferably 350 to 410° C., 100 to 1000 pounds per square inch (psi) (0.689-6.89 MPa) for up to about three hours. Additional layers can be present, for example, additional conductive layers, substrates, and/or bond ply layers, to make a circuit assembly.

In another embodiment, one or more composite dielectric layers can be layered on or between one or more single clad or double clad laminates. The dielectric layers can be B-staged, that is, partially cured. The stack can then be placed in a press, e.g. a vacuum press, under a pressure and temperature and for duration of time suitable to bond the layers and form a laminate. Lamination and curing can be by a one-step process, for example using a vacuum press, or by a multiple-step process. In an exemplary one-step process the stack can be placed in a press, brought up to laminating pressure (e.g., about 150 to about 400 psi) and heated to laminating temperature (e.g., about 170 to about 390° C.). The laminating temperature and pressure are maintained for the desired soak time, i.e., about 20 minutes to about 3 hours, and thereafter cooled (while still under pressure) to below about 150° C.

In an exemplary multiple-step process, a peroxide cure step at temperatures of about 150° C. to about 200° C. can be conducted, and the partially cured stack can then be subjected to a high-energy electron beam irradiation cure (E-beam cure) or a high temperature cure step under an inert atmosphere. Use of a two-stage cure can impart an unusually high degree of cross-linking to the resulting laminate. The temperature used in the second stage is typically about 250° C. to about 300° C., or the decomposition temperature of the polymer. This high temperature cure can be carried out in an oven but can also be performed in a press, namely as a continuation of the initial lamination and cure step. Particular lamination temperatures and pressures will depend upon the particular adhesive composition and the substrate composition, and are readily ascertainable by one of ordinary skill in the art without undue experimentation.

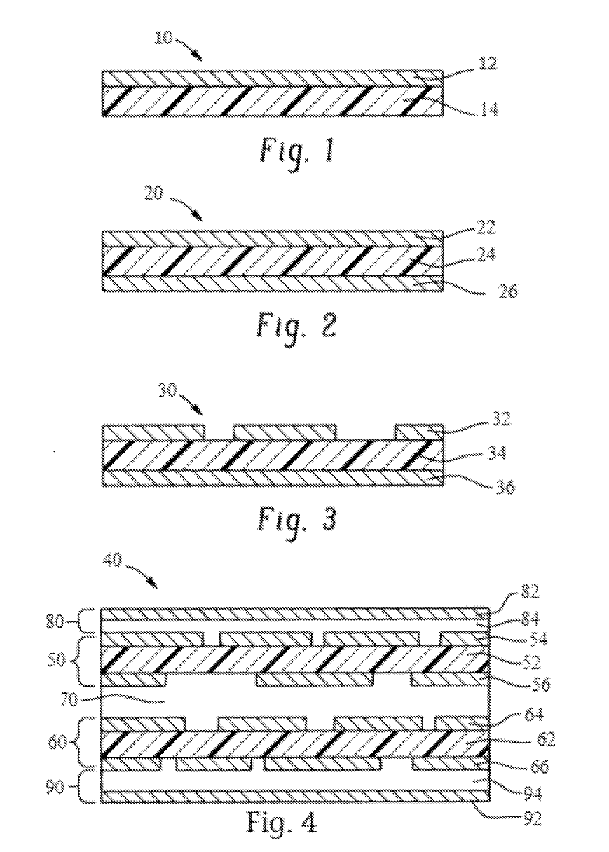

Referring now to FIG. 1, an exemplary circuit subassembly is illustrated. The subassembly is a single clad laminate 10 comprising a conductive metal layer 12 disposed on and in contact with a dielectric substrate layer 14. The dielectric substrate layer 14 comprises the crosslinked fluoropolymer and can optionally also include a particulate filler such that a dielectric composite material is formed thereby. An optional glass web (not shown) can be present in dielectric substrate layer 14. It is to be understood that in all of the embodiments described herein, the various layers can fully or partially cover each other, and additional conductive layers, patterned circuit layers, and dielectric layers can also be present. Optional adhesive (bond ply) layers (not shown) can also be present, and can be uncured or partially cured. Many different multi-layer circuit configurations can be formed using the above laminates.

Another embodiment of a multilayer circuit assembly is shown at 20 in FIG. 2. Double clad circuit layer 20 comprises conductive layers 22, 26 disposed on opposite sides of a dielectric substrate layer 24. The dielectric substrate layer 24 comprises the crosslinked fluoropolymer and can optionally also include a particulate filler or woven glass web, e.g., such that a dielectric composite material is formed thereby. Dielectric substrate layer 24 can also comprise a woven or nonwoven web (not shown).

A circuit subassembly 30 is shown in FIG. 3, comprising a circuit layer 32 and a conductive layer 36 disposed on opposite sides of a dielectric substrate layer 34. The dielectric substrate layer 34 comprises the crosslinked fluoropolymer and can optionally also include a filler(s) (e.g. particulate filler) such that a dielectric composite material is formed thereby. Dielectric substrate layer 34 can also comprise a woven or nonwoven web (not shown).

FIG. 4 shows an exemplary multilayer circuit assembly 40 having a first double clad circuit 50, a second double clad circuit 60, and a bond ply 70 disposed therebetween. Double clad circuit 50 comprises a dielectric substrate 52 disposed between two conductive circuit layers 54, 56. Double clad circuit 60 comprises a dielectric substrate 62 disposed between two conductive circuit layers 64, 66. One or both of dielectric substrates 52, 62 can comprise a filler or woven or nonwoven web, e.g., such that a dielectric composite material is formed thereby. Each dielectric substrate layer 52, 62 can comprise a woven or nonwoven glass reinforcement (not shown). Two cap layers 80, 90 are also shown. Each cap layer 80, 90, respectively include a conductive layer 82, 92 disposed on a bond ply layer 84, 94. One or more of the dielectric substrates and/or one or more of the bond plies comprise a crosslinked fluoropolymer. One or more of dielectric substrates and/or one or more of the bond plies can optionally also comprise a filler.

One, two, or more bond plies can be used. In some embodiments, the three-layer bond ply includes an intermediate layer comprising a thermosetting composition and a filler, sandwiched respectively between first outer layer and second outer layer comprising the thermosetting composition and the filler, wherein the thermosetting composition of the intermediate layer has a degree of cure that is greater than a degree of cure of each thermosetting composition of the outer layers. At least one of the thermosetting compositions of the layers in the bond ply includes at least one crosslinked fluoropolymer matrix material. In some case, more than one or all of the thermosetting compositions can include at least one crosslinked fluoropolymer matrix material. The amount of filler in each layer can be the same or it can be different. Regardless of the ratio of thermosetting composition and filler composition within each layer, the thermosetting composition of the intermediate layer will have a degree of cure that is greater than the degree of cure of each of the thermosetting compositions of the first and the second outer layers. For example, the intermediate layer can be fully cured, while the outer layers are cured to a lesser degree, such as a layer uncured or B-staged.

In addition, multilayer circuits can be made by using a multi-layer bond ply to bond multiple layers of circuit subassemblies into a single stacked circuit containing many circuitized conductive layers. Exemplary circuit subassemblies can include, without limitation, single clad laminates, double clad laminates, and the like. A single clad laminate, for example, comprises a conductive metal layer disposed on and in contact with a dielectric substrate layer. It is to be understood that in all of the embodiments described herein, the various layers can fully or partially cover each other, and additional conductive layers, patterned circuit layers, and dielectric layers can also be present. Optional adhesive layers (not shown) can also be present. A double clad circuit laminate comprises two conductive layers disposed on opposite sides of a dielectric substrate layer. One or both of the conductive layers can be in the form of a circuit.

There are no particular limitations regarding the thickness of the conductive layer, nor are there any limitations as to the shape, size, or texture of the surface of the conductive layer. Preferably however, the conductive layer comprises a thickness of about 3 micrometers to about 200 micrometers, in some cases about 9 micrometers to about 180 micrometers. When two or more conductive layers are present, the thickness of the two layers can be the same or different.

One or more of the dielectric substrate layers, for example in the double clad laminates, can comprise a dielectric material the same as that of the dielectric thermosetting composition of the bond ply, or the dielectric material in the substrate layer(s) can be different from the dielectric material in the bond ply. Dielectric materials that can be used include, for example, glass fiber-reinforced epoxy or bismaleimide triazine (BT) resin, and other low polarity, low dielectric constant and low loss resins such as those based on resins such as 1,2-polybutadiene, polyisoprene, poly(etherimide) (PEI), crosslinked and uncrosslinked polytetrafluoroethylene (PTFE) crosslinked and uncrosslinked PFA, liquid crystal polymers, polyaryleneetherketones, polybutadiene-polyisoprene copolymers, poly(phenylene ether)s, and those based on allylated poly(phenylene ether)s. Combinations of low polarity materials with higher polarity materials can also be used, non-limiting examples including epoxy and poly(phenylene ether), epoxy and poly(ether imide), and cyanate ester and poly(phenylene ether). Such material can optionally further include woven, thermally stable webs of a suitable fiber, specifically glass (E, S, and D glass) or high temperature polyester fibers (e.g., KODEL from Eastman Chemical).

The single clad and double clad laminates and the multilayer circuit illustrated for example in FIG. 4 can be formed by means known in the art. In some embodiments, the lamination process entails placing layers of the dielectric material between one or two sheets of coated or uncoated conductive layers (an adhesive layer can be disposed between at least one conductive layer and at least one dielectric substrate layer) to form a circuit substrate. The layered material can then be placed in a press, e.g. a vacuum press, under a pressure and temperature and for a duration of time suitable to bond the layers and form a laminate. The same can be done to form the multilayer circuit. The three-layer bond ply is disposed between the two double clad laminates and the assembly can then be placed in a press, e.g. a vacuum press, under a pressure and temperature and for a duration of time suitable to bond the outer layers of the bond ply to the circuitized conductive layers of the double clad laminates. Lamination and curing can be by a one-step process, for example using a vacuum press, or by a multiple-step process.

Embodiment 1. A circuit subassembly, comprising a conductive layer disposed on a dielectric layer, wherein the dielectric layer comprises a crosslinked fluoropolymer.

Embodiment 2. The circuit subassembly of Embodiment 1, wherein the dielectric layer further comprises a particulate filler, glass reinforcement, or both.

Embodiment 3. The circuit subassembly of Embodiments 1 or 2, wherein the particulate filler comprises silica, titania, or a combination comprising at least one of the foregoing.

Embodiment 4. The circuit subassembly of any of Embodiments 1 to 3, wherein the fluoropolymer is a polymer of tetrafluoroethylene, vinylidene fluoride, chlorotrifluoroethylene, perfluoroether, tetrafluoroethylene-perfluoropropylene vinyl ether, or a combination comprising at least one of the foregoing, optionally with a comonomer.

Embodiment 5. The circuit subassembly of Embodiment 4, wherein the comonomer is perfluoromethyl vinyl ether, perfluoropropylene vinyl ether, hexafluoropropylene, perfluorobutyl ethylene, ethylene, propylene, butylene, or a combination comprising at least one of the foregoing.

Embodiment 6. The circuit subassembly of any of Embodiments 1-5, wherein the fluoropolymer is polytetrafluoroethylene, tetrafluoroethylene-perfluoropropylene vinyl ether copolymer, tetrafluoroethylene-hexafluoropropylene copolymer, ethylene-tetrafluoroethylene copolymer, polychlorotrifluoroethylene, polyvinylidene fluoride, polyvinyl fluoride, or a combination comprising at least one of the foregoing.

Embodiment 7. The circuit subassembly of Embodiment 6, wherein the fluoropolymer is polytetrafluoroethylene.

Embodiment 8. The circuit subassembly of any of Embodiments 1-7, wherein the circuit subassembly is a circuit laminate.

Embodiment 9. The circuit subassembly of Embodiment 8, further comprising a second conductive layer disposed on a side of the dielectric layer opposite the first conductive layer.

Embodiment 10. The circuit subassembly of any of Embodiments 1-9, wherein the circuit subassembly is a resin-coated conductive layer.

Embodiment 11. The circuit subassembly of any of Embodiments 1-10, wherein the conductive layer is copper.

Embodiment 12. The circuit subassembly of any of Embodiments 1-11, wherein the conductive layer is circuitized.

Embodiment 13. The circuit subassembly of any of Embodiments 1-12, wherein the conductive layer is in direct contact with the dielectric layer.

Embodiment 14. The circuit subassembly of any of Embodiments 1-12, further comprising a bond ply disposed between and in contact with the conductive layer and the dielectric substrate layer.

Embodiment 15. The circuit subassembly of Embodiment 14, wherein the bond ply comprises a crosslinked fluoropolymer.

Embodiment 16. A circuit comprising the circuit subassembly of any of Embodiments 1-15.

Embodiment 17. A multi-layer circuit comprising the circuit subassembly of any of Embodiments 1-16.

Embodiment 18. A method of making the circuit subassembly of any of Embodiments 1-17, the method comprising: disposing a conductive layer on a dielectric substrate layer, wherein the dielectric layer comprises a crosslinked fluoropolymer; and laminating the dielectric substrate layer and the conductive layer under heat and pressure.

Embodiment 19. The method of Embodiment 18, wherein a bond ply is disposed between and in contact with the conductive layer and the dielectric layer before laminating.

Embodiment 20. A circuit comprising the circuit subassembly formed by the method of any of Embodiments 18-19.

Ranges disclosed herein are inclusive of the recited endpoint and are independently combinable. “Combination” is inclusive of blends, mixtures, alloys, reaction products, and the like. Also, “combinations comprising at least one of the foregoing” means that the list is inclusive of each element individually, as well as combinations of two or more elements of the list, and combinations of one or more elements of the list with non-list elements. The terms “first,” “second,” and so forth, herein do not denote any order, quantity, or importance, but rather are used to distinguish one element from another. The terms “a” and “an” herein do not denote a limitation of quantity, but rather denote the presence of at least one of the referenced item. “Or” means “and/or.” Also, as used herein, “disposed” means at least partial intimate contact between two layers and includes layers that partially or wholly cover each other. In addition, it is to be understood that the described elements can be combined in any suitable manner in the various embodiments.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While the invention has been described with reference to several embodiments thereof, it will be understood by those skilled in the art that various changes can be made and equivalents can be substituted for elements thereof without departing from the scope of the invention. In addition, many modifications can be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

What is claimed is:

1. A circuit subassembly, comprising a conductive layer disposed on a dielectric layer, wherein the dielectric layer comprises a crosslinked fluoropolymer.

2. The circuit subassembly of claim 1, wherein the dielectric layer further comprises a particulate filler, glass reinforcement, or both.

3. The circuit subassembly of claim 2, wherein the particulate filler comprises silica, titania, or a combination comprising at least one of the foregoing.

4. The circuit subassembly of claim 1, wherein the fluoropolymer is a polymer of tetrafluoro ethylene, vinylidene fluoride, chlorotrifluoroethylene, perfluoroether, tetrafluoroethylene-perfluoropropylene vinyl ether, or a combination comprising at least one of the foregoing, optionally with a comonomer.

5. The circuit subassembly of claim 4, wherein the comonomer is perfluoromethyl vinyl ether, perfluoropropylene vinyl ether, hexafluoropropylene, perfluorobutyl ethylene, ethylene, propylene, butylene, or a combination comprising at least one of the foregoing.

6. The circuit subassembly of claim 1, wherein the fluoropolymer is polytetrafluoro ethylene, tetrafluoroethylene-perfluoropropylene vinyl ether copolymer, tetrafluoroethylene-hexafluoropropylene copolymer, ethylene-tetrafluoroethylene copolymer, polychlorotrifluoroethylene, polyvinylidene fluoride, polyvinyl fluoride, or a combination comprising at least one of the foregoing.

7. The circuit subassembly of claim 6, wherein the fluoropolymer is polytetrafluoro ethylene.

8. The circuit subassembly of claim 1, wherein the circuit subassembly is a circuit laminate.

9. The circuit subassembly of claim 8, further comprising a second conductive layer disposed on a side of the dielectric layer opposite the conductive layer.

10. The circuit subassembly of claim 1, wherein the circuit subassembly comprises a resin-coated conductive layer.

11. The circuit subassembly of claim 1, wherein the conductive layer is copper.

12. The circuit subassembly of claim 1, wherein the conductive layer is circuitized.

13. The circuit subassembly of claim 1, wherein the conductive layer is in direct contact with the dielectric layer.

14. The circuit subassembly of claim 1, further comprising a bond ply disposed between and in contact with the conductive layer and the dielectric substrate layer.

15. The circuit subassembly of claim 14, wherein the bond ply comprises a crosslinked fluoropolymer.

16. A circuit comprising the circuit subassembly of claim 1.

17. A multi-layer circuit comprising the circuit subassembly of claim 1.

18. A method of making the circuit subassembly of claim 1, the method comprising:
disposing a conductive layer on a dielectric substrate layer, wherein the dielectric layer comprises a crosslinked fluoropolymer; and
laminating the dielectric substrate layer and the conductive layer under heat and pressure.

19. The method of claim 18, wherein a bond ply is disposed between and in contact with the conductive layer and the dielectric layer before laminating.

20. A circuit comprising the circuit subassembly formed by the method of claim 18.
